(19) United States
(12) Patent Application Publication
(10) Pub. No.: US 2026/0085003 A1
(43) Pub. Date: Mar. 26, 2026

(54) WINDOW MANUFACTURING METHOD, WINDOW MANUFACTURED BY THE METHOD, AND ELECTRONIC APPARATUS INCLUDING THE WINDOW

(71) Applicant: Samsung Display Co., LTD., Yongin-si (KR)

(72) Inventors: Hoikwan LEE, Yongin-si (KR); Sangduk LEE, Yongin-si (KR)

(21) Appl. No.: 19/223,829

(22) Filed: May 30, 2025

(30) Foreign Application Priority Data
Sep. 25, 2024 (KR) 10-2024-0129520

(51) Int. Cl. C03C 23/00; C03C 15/00; G06F 1/16; H10K 59/80

(52) U.S. Cl. CPC C03C 23/007; C03C 15/00; G06F 1/1652; H10K 59/871

(57) ABSTRACT

Provided is a method of manufacturing a window, the method including preparing a mother glass substrate including silicon dioxide (SiO₂), forming a first preliminary window by applying heat to the mother glass substrate, forming a second preliminary window by providing water onto the first preliminary window, forming a third preliminary window by etching the second preliminary window, and forming a window by exposing the third preliminary window to an acidic solution. Accordingly, the method of manufacturing a window may exhibit excellent processability, and a window manufactured by the same method may achieve excellent durability.

This application claims priority to Korean Patent Application No. 10-2024-0129520, filed on Sep. 25, 2024, and all the benefits accruing therefrom under 35 U.S.C. § 119, the content of which in its entirety is herein incorporated by reference.

### BACKGROUND

The present disclosure herein relates to a window manufacturing method including steps of providing heat and water, a window manufactured by the method, and an electronic apparatus including the window.

Various display devices used for multimedia devices such as, for example, a television, a mobile phone, a tablet computer, and a game console are being developed. A display device may include a display panel which generates images and videos, and a window member for protecting the display panel. The window member includes an anti-glare layer and an anti-reflection layer arranged on a glass substrate so as to improve display quality, which results in an increase in a thickness of a device and manufacturing costs.

### SUMMARY

The present disclosure provides a window manufacturing method exhibiting excellent processability.

The present disclosure also provides a window exhibiting excellent durability and an electronic apparatus including the same.

An embodiment of the inventive concept provides a method of manufacturing a window, the method including: preparing a mother glass substrate including silicon dioxide (SiO₂); forming a first preliminary window by applying heat to the mother glass substrate; forming a second preliminary window by providing water onto the first preliminary window; forming a third preliminary window by etching the second preliminary window; and forming a window by exposing the third preliminary window to an acidic solution.

In an embodiment, a temperature of the heat may range from about 100° C. to about 200° C.

In an embodiment, the water may be provided onto the first preliminary window through a spraying method.

In an embodiment, etching the second preliminary window may include providing an etchant.

In an embodiment, the etchant may include at least one of hydrogen fluoride (HF), ammonium fluoride (NH₄F), or ammonium hydrogen fluoride (NH₄HF₂).

In an embodiment, the acidic solution may include at least one of hydrochloric acid (HCl), nitric acid (HNO₃), or sulfuric acid (H₂SO₄).

In an embodiment, a temperature of the acidic solution may range from about 40° C. to about 80° C.

In an embodiment, the third preliminary window may be exposed to the acidic solution for a time period ranging from about 5 minutes to about 15 minutes.

In an embodiment, an acidic component may be contained in an amount of about 20 wt % to about 80 wt % with respect to 100 wt % of a total weight of the acidic solution.

In an embodiment, forming the window may include immersing the third preliminary window in the acidic solution.

In an embodiment, the window may include an upper surface and a lower surface facing the upper surface, and a first concentration of silicon in a portion of the window including the upper surface may be higher than a second concentration of silicon in another portion of the window.

In an embodiment, the portion of the window including the upper surface may have a thickness ranging from about 20 nm to about 200 nm.

In an embodiment, the window may have a surface roughness ranging from about 10 nm to about 1000 nm.

In an embodiment of the inventive concept, a window which is a glass substrate includes: an upper surface including a convex portion and a concave portion; a lower surface facing the upper surface; and silicon dioxide, wherein the upper surface has a surface roughness ranging from about 10 nm to about 1000 nm, a first concentration of silicon in a portion of the window which is spaced apart from the lower surface and includes the upper surface is higher than a second concentration of silicon in another portion of the window, and the portion of the window including the upper surface has a thickness ranging from about 20 nm to about 200 nm.

In an embodiment, the window may be a single layer.

In an embodiment, the lower surface may be flat.

In an embodiment of the inventive concept, an electronic apparatus includes: a display device having a module region defined therein, and an electronic module disposed to correspond to the module region, wherein the display device includes a display panel and a window disposed on the display panel, the window which is a glass substrate includes an upper surface including a convex portion and a concave portion, a lower surface facing the upper surface, and silicon dioxide, the upper surface has a surface roughness ranging from about 10 nm to about 1000 nm, a first concentration of silicon in a portion of the window which is spaced apart from the lower surface and includes the upper surface is higher than a second concentration of silicon in another portion of the window, and the portion of the window including the upper surface has a thickness ranging from about 20 nm to about 200 nm.

In an embodiment, the upper surface may be spaced apart from the display panel, with the lower surface between the upper surface and the display panel.

In an embodiment, the window may be a single layer.

In an embodiment, the lower surface of the window may be flat.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view illustrating an electronic apparatus according to an embodiment;

FIG. 2 is an exploded perspective view illustrating an electronic apparatus according to an embodiment;

FIG. 3 is a cross-sectional view illustrating a portion taken along line I-I′ of FIG. 2;

FIG. 4A is an enlarged cross-sectional view illustrating region XX′ of FIG. 3;

FIG. 4B is a cross-sectional view illustrating a window according to an embodiment;

FIG. 4C is a cross-sectional view illustrating a window according to an embodiment;

FIG. 5 is a cross-sectional view illustrating a portion of an electronic apparatus according to an embodiment;

FIG. 6A is a perspective view illustrating an electronic apparatus according to an embodiment;

FIG. 6B is a perspective view illustrating an electronic apparatus according to an embodiment;

FIG. 6C is a plan view illustrating an electronic apparatus according to an embodiment;

FIG. 6D is a perspective view illustrating an electronic apparatus according to an embodiment;

FIG. 7 is an exploded perspective view illustrating an electronic apparatus according to an embodiment;

FIG. 8 is a flowchart illustrating a window manufacturing method according to an embodiment;

FIG. 9 is a view schematically illustrating a window manufacturing step according to an embodiment;

FIG. 10 is a view schematically illustrating a window manufacturing step according to an embodiment;

FIG. 11 is a view schematically illustrating a window manufacturing step according to an embodiment;

FIG. 12 is a view schematically illustrating a window manufacturing step according to an embodiment;

FIG. 13 is a graph illustrating a transmittance of a window according to a wavelength;

FIG. 14 is a block diagram of an electronic apparatus according to an embodiment; and

FIG. 15 shows schematic views of electronic apparatuses according to various embodiments.

### DETAILED DESCRIPTION

The inventive concept may be implemented in various modifications and have various forms, and specific embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the inventive concept.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. In some aspects, in the drawings, the thickness, the ratio, and the dimension of the elements are exaggerated for effective description of the technical contents. The term “and/or” includes all combinations of one or more of the associated listed elements.

Although the terms first, second, and the like, may be used to describe various elements, these elements should not be limited by these terms. These terms are used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

In some aspects, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially perpendicular” means approximately or actually perpendicular. The term “substantially parallel” means approximately or actually parallel.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. In some aspects, terms, such as those defined in commonly used dictionaries, should be interpreted as having a meaning that is consistent with their meaning in the context of the relevant art and should not be interpreted in an idealized or overly formal sense unless expressly so defined herein.

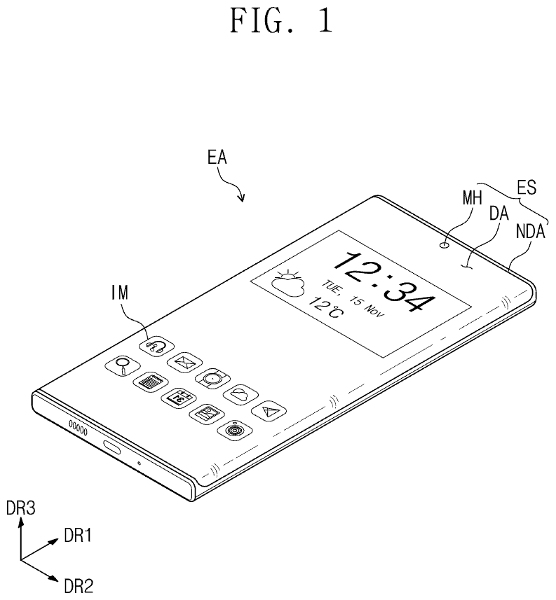

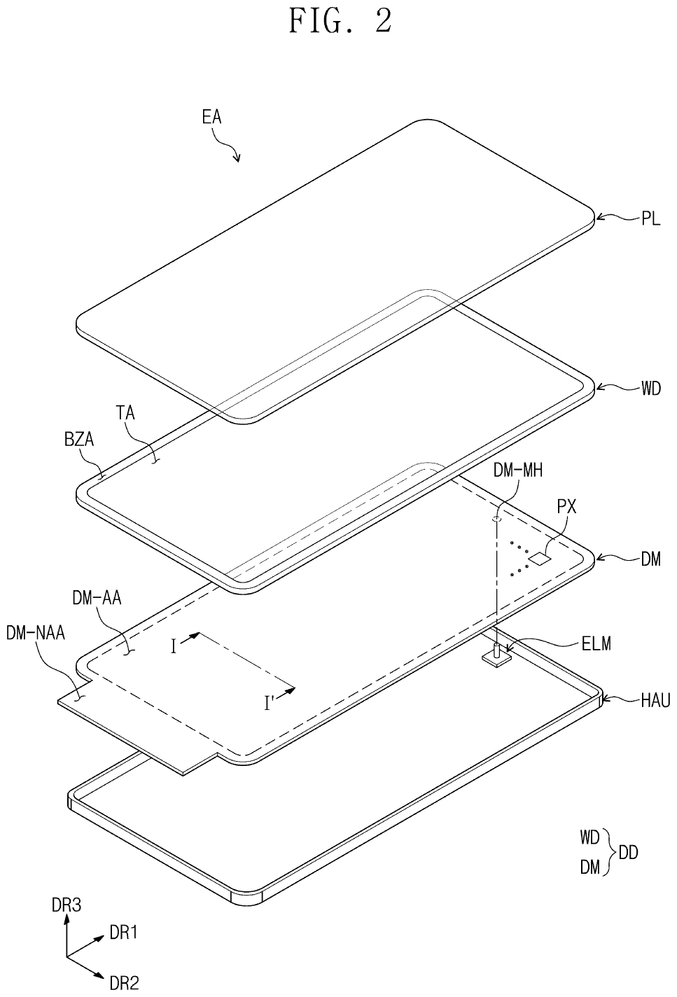

Hereinafter, a window according to an embodiment of the inventive concept and an electronic apparatus including the same will be described with reference to the drawings. FIG. 1 is a perspective view illustrating an electronic apparatus according to an embodiment. FIG. 2 is an exploded perspective view of an electronic apparatus according to an embodiment.

An electronic apparatus EA, according to an embodiment, which is illustrated in FIG. 1 may be activated in response to an electrical signal. For example, the electronic apparatus EA may be a personal computer, a laptop computer, a personal digital terminal, a game console, a portable electronic device, a television, a monitor, an outdoor billboard, a car navigation unit, or a wearable apparatus, but embodiments of the present disclosure are not limited thereto. In FIG. 1, the electronic apparatus EA is illustrated as a smart phone as an example.

The electronic apparatus EA may include a display surface ES defined by a first direction axis DR1 and a second direction axis DR2 crossing the first direction axis DR1. The electronic apparatus EA may provide an image IM to a user through the display surface ES. The electronic apparatus EA may display the image IM, in the direction of a third direction axis DR3, on the display surface ES parallel to each of the first direction axis DR1 and the second direction axis DR2. The image IM may include not only a dynamic image but also a static image.

The directions indicated by the first to third direction axes DR1, DR2, and DR3 illustrated herein have a relative concept, and may thus be changed to other directions. In some aspects, the directions indicated as the first to third direction axes DR1, DR2, and DR3 may be referred to as first to third directions, and may be denoted as the same reference numerals or symbols.

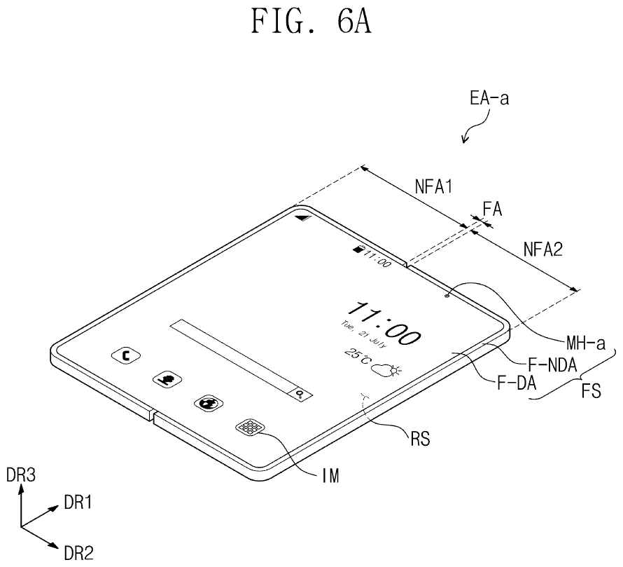

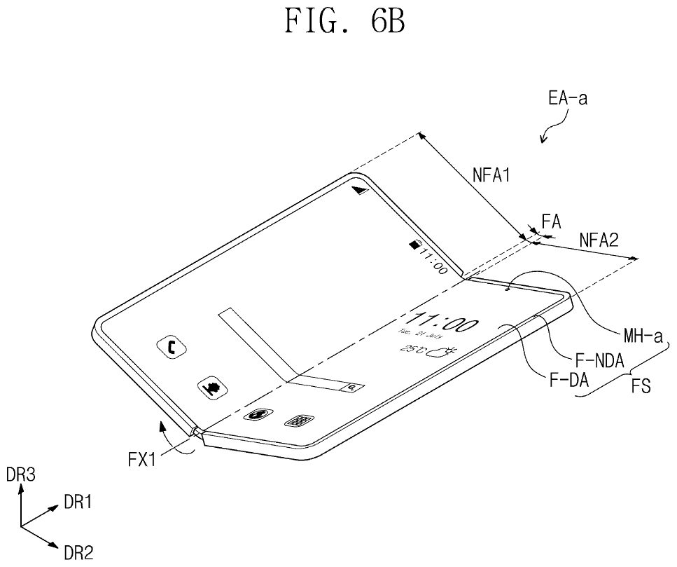

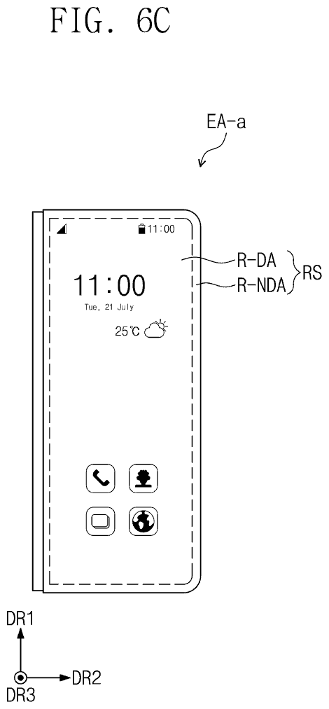

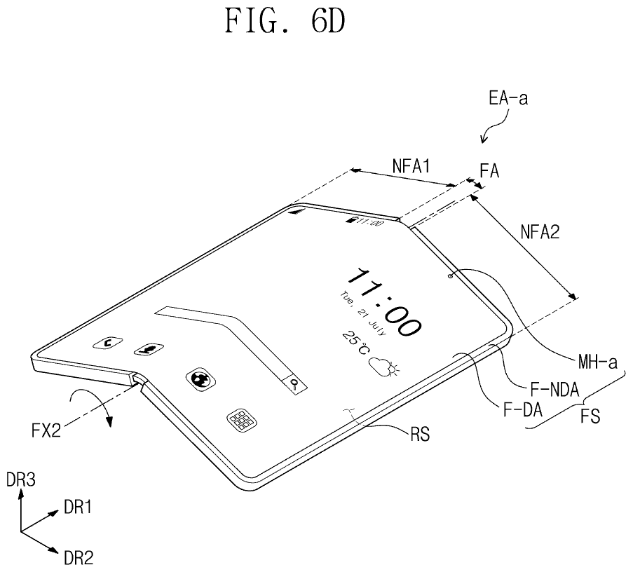

In this specification, the first direction axis DR1 is perpendicular to the second direction axis DR2, and the third direction axis DR3 may be a normal direction of the plane defined by the first direction axis DR1 and the second direction axis DR2. A thickness direction of the electronic apparatus EA may be a direction parallel to the third direction axis DR3. The same reference numerals or symbols may be used for the thickness direction of the electronic apparatus EA and the third direction axis DR3. A front surface (or an upper surface) and a rear surface (or a lower surface) may be opposed to each other in the third direction axis DR3, and a normal direction of each of the front surface (or the upper surface) and the rear surface (or the lower surface) may be parallel to the third direction axis DR3. The front surface (or the upper surface) is referred to as a surface adjacent to the display surface ES, and the rear surface (or the lower surface) is referred to as a surface spaced apart from the display surface ES. In some aspects, the rear surface (or the lower surface) is referred to as a surface adjacent to a second display surface RS (see FIG. 6A) to be described later. An upper side is referred to as a direction of getting closer to the display surface ES, and a lower side is referred to as a direction of getting farther away from the display surface ES.

In this specification, a cross section is referred to as a surface parallel to the thickness direction DR3, and a plane is referred to as a surface perpendicular to the thickness direction DR3. The plane is referred to as a surface parallel to a plane defined by the first direction axis DR1 and the second direction axis DR2.

In this specification, the wording “substantially the same” includes a case where physical values are the same and a case where a difference falls within a process tolerance range.

The electronic apparatus EA may detect an external input applied from the outside. The external input may include various types of inputs applied from the outside of the electronic apparatus EA. For example, the external input may include not only a touch by a part of a user's body such as, for example, user's hands but also an external input (for example, hovering) applied while approaching or being adjacent within a predetermined distance to the electronic apparatus EA. In some aspects, the external input may have various forms such as, for example, force, pressure, temperature, light, or the like.

The display surface ES may include a display region DA, a non-display region NDA, and a sub-region MH. The display region DA may be activated in response to an electrical signal. The display region DA may be a region in which the image IM may be displayed and various types of external inputs may be detected.

The display region DA may include a flat surface defined by the first direction axis DR1 and the second direction axis DR2. The display region DA may include a curved surface bent from at least one side of the flat surface defined by the first direction axis DR1 and the second direction axis DR2. It is illustrated that in the electronic apparatus EA illustrated in FIG. 1, the display region DA includes two curved surfaces which are respectively bent from both sides of the flat surface defined by the first direction axis DR1 and the second direction axis DR2. However, this is presented as an example, and a shape of the display region DA is not limited thereto. For example, the display region DA may include the flat surface defined by the first direction axis DR1 and the second direction axis DR2, as well as may further include at least two curved surfaces, for example, four curved surfaces respectively bent from four side surfaces of the flat surface defined by the first direction axis DR1 and the second direction axis DR2.

The electronic apparatus EA according to an embodiment may be flexible. The term “flexible” means a bendable property, and may include all of a completely foldable structure as well as a structure which is bendable to the level of several nanometers. For example, the electronic apparatus EA may be a rigid apparatus. On the contrary, the electronic apparatus EA may be a foldable apparatus.

The non-display region NDA may have a predetermined color. The non-display region NDA may be adjacent to the display region DA. The non-display region NDA may surround the display region DA. Accordingly, a shape of the display region DA may be substantially defined by the non-display region NDA. However, this is presented as an example. The non-display region NDA may be disposed to be adjacent to a single side of the display region DA as well as be omitted. The display region DA may be provided to have various shapes, and is not limited to any one embodiment.

The sub-region MH may detect an external subject received through the display surface ES or provide a sound signal such as, for example, voice to the outside through the display surface ES. An optical signal such as, for example, visible light or infrared light may move to the sub-region MH. The sub-region MH may be disposed within the display region DA. However, this is illustrated as an example, and an arrangement of the sub-region MH is not limited to any one embodiment. For example, the sub-region MH may not only be surrounded by the non-display region NDA but also be surrounded by the display region DA and the non-display region NDA. FIG. 1 and other figures herein illustrate one sub-region MH, but the sub-region MH may also be provided in plurality.

Various electronic modules ELM (see FIG. 2) may be disposed so as to correspond to the sub-region MH. For example, the electronic module ELM (see FIG. 2) may include at least one of a camera, a speaker, a light detection sensor, or a heat detection sensor. The electronic apparatus EA may include the electronic module ELM (see FIG. 2) which captures an external image by using visible light passing through the sub-region MH or determines whether an external object is approaching by using infrared light. The electronic module ELM (see FIG. 2) may also include a plurality of elements, and is not limited to any one embodiment.

Referring to FIG. 2, the electronic apparatus EA may include a display device DD and the electronic module ELM. The display device DD may include a display module DM and a window member WD disposed on the display module DM. In some aspects, the electronic apparatus EA may further include a housing HAU and a protective layer PL. In the display device DD, a module region DM-MH may be defined, and the electronic module ELM may also be disposed so as to correspond to the module region DM-MH.

In the electronic apparatus EA illustrated in FIGS. 1 and 2, the housing HAU may be disposed below the display module DM. The housing HAU may include a material having relatively high rigidity. For example, the housing HAU may include a plurality of frames and/or plates composed of glass, plastic, or metal. The display module DM may be accommodated in the housing HAU. The housing HAU may provide a predetermined accommodation space. The display module DM may be accommodated inside the accommodation space and be protected against external impacts.

The protective layer PL may be disposed on the window member WD. The protective layer PL may be a functional layer which protects one surface of the window member WD (for example, an upper surface). For example, the protective layer PL may include polyethylene terephthalate (PET). The protective layer PL may include an anti-fingerprint coating agent, an antistatic agent, a hard coating agent, or the like.

The display module DM may be activated in response to an electrical signal. The display module DM may be activated to display the image IM (see FIG. 1) on the display region DA (see FIG. 1) of the electronic apparatus EA. An active region DM-AA, a peripheral region DM-NAA, and the module region DM-MH may be defined in the display module DM.

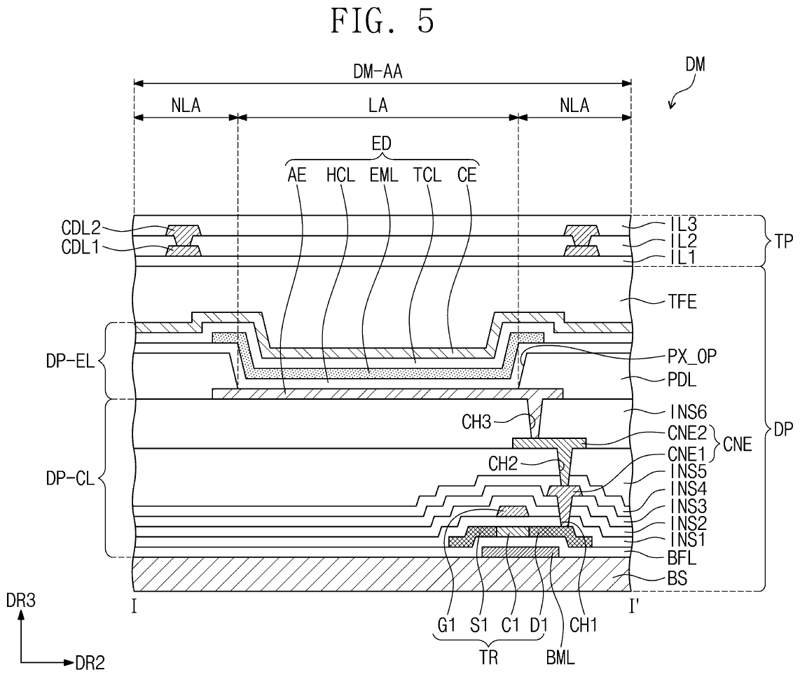

The active region DM-AA may be activated in response to an electrical signal. A pixel PX may be disposed in the active region DM-AA. The pixel PX may include a transistor TR (see FIG. 5) and a light-emitting element ED (see FIG. 5) to be described later. The peripheral region DM-NAA may be located to be adjacent to at least one side of the active region DM-AA. A circuit, line, or the like for driving the active region DM-AA may be disposed in the peripheral region DM-NAA.

The module region DM-MH may correspond to the sub-region MH illustrated in FIG. 1. An optical signal such as, for example, visible light or infrared light may move to the module region DM-MH. The module region DM-MH may be disposed within the active region DM-AA. On the contrary, the module region DM-MH may not only be surrounded by the peripheral region DM-NAA but also be surrounded by the active region DM-AA and the peripheral region DM-NAA. A position of the module region DM-MH is not limited to any one embodiment.

The electronic module ELM may be an electronic component which outputs or receives an optical signal. For example, the electronic module ELM may include a camera module and/or a proximity sensor. The camera module may capture an external image via the module region DM-MH.

Although not illustrated, the display device DD may further include an optical layer disposed between the display module DM and the window member WD. The optical layer may be formed on the display module DM through a continuous process. The optical layer may include a polarization plate or a color filter layer. For example, the optical layer may include at least one of a retarder, a polarizer, a polarization film, or a polarization filter. Alternatively, the optical layer may include a plurality of color filters disposed in a predetermined arrangement. For example, the color filters may be arranged in consideration of light-emitting colors of the pixels PX. In some aspects, the optical layer may further include a black matrix adjacent to the color filters.

The window member WD may include a transmission region TA and a bezel region BZA. The transmission region TA may overlap at least a portion of the active region DM-AA of the display module DM. The transmission region TA may be an optically transparent region. The image IM (see FIG. 1) may be provided to a user through the transmission region TA.

The bezel region BZA may be a region having a relatively lower light transmittance than the transmission region TA. The bezel region BZA may define a shape of the transmission region TA. The bezel region BZA may be adjacent to the transmission region TA and surround the transmission region TA.

The bezel region BZA may have a predetermined color. The bezel region BZA may cover the peripheral region DM-NAA of the display module DM and prevent the peripheral region DM-NAA from being viewed from the outside. However, an embodiment of the inventive concept is not limited to what is illustrated in the drawings. The bezel region BZA may be disposed adjacent to a single side of the transmission region TA, as well as at least a portion thereof may be omitted.

Although not illustrated, an adhesive layer may be disposed below the window member WD. A component (for example, the display module DM) disposed below the window member WD may be bonded to the window member WD via the adhesive layer. For example, the adhesive layer may include a pressure sensitive adhesive (PSA), an optically clear adhesive film (OCA) or an optically clear adhesive resin layer (OCR).

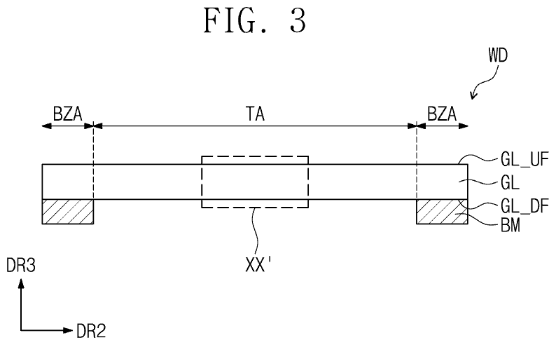

FIG. 3 is a cross-sectional view illustrating a window member WD according to an embodiment. Referring to FIG. 3, the window member WD may include a window GL. The window GL may be optically transparent. The image IM (see FIG. 1) displayed on the display module DM (see FIG. 2) may pass through the window GL and be viewed by a user.

The window GL is a single-layered glass substrate, and the glass substrate may include silicon dioxide (SiO₂). The window GL which is a single-layered glass substrate may have an anti-glare property and an anti-reflection property. A member having an anti-glare property and a member having an anti-reflection property may not be disposed on the window GL. The window GL has a single-layered structure, but may perform multiple functions (that is, includes an anti-glare function and an anti-reflection function). Accordingly, the window GL according to an embodiment may exhibit excellent optical properties (that is, an anti-glare property and an anti-reflection property) and excellent durability, and the electronic apparatus EA (see FIG. 2) including the window GL may achieve excellent reliability and excellent display quality.

In some aspects, the window member WD may further include a printed layer BM disposed on a lower surface GL_DF of the window GL. The window GL may include the lower surface GL_DF and an upper surface GL_UF facing the lower surface GL_DF. The lower surface GL_DF and the upper surface GL_UF of the window GL may have an integral shape. The lower surface GL_DF of the window GL may be adjacent to the display module DM (see FIG. 2). The upper surface GL_UF of the window GL may be spaced apart from the display module DM (see FIG. 2), with the lower surface GL_DF of the window GL between the upper surface GL_UF and the display module DM. The upper surface GL_UF of the window GL may be spaced apart from a display panel DP (see FIG. 5) included in a display module DM (see FIG. 5), with the lower surface GL_DF of the window GL between the upper surface GL_UF and the display panel DP. The upper surface GL_UF of the window GL may be a surface of the window GL.

The printed layer BM may be disposed in an edge region of the window GL. The printed layer BM may cover the peripheral region DM-NAA (see FIG. 2) and block the peripheral region DM-NAA (see FIG. 2) from being viewed from the outside. The bezel region BZA may be a portion to which the printed layer BM is provided. The printed layer BM may be an ink printed layer. In some aspects, the printed layer BM may be a layer formed by providing a pigment or a dye. For example, the printed layer BM may be a layer formed by providing a black pigment or a black dye.

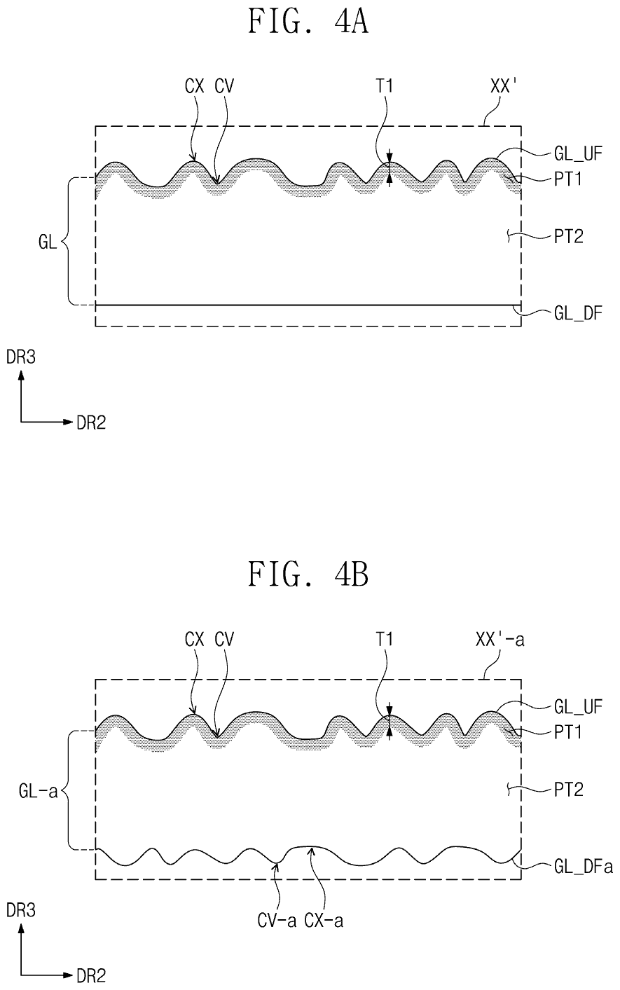

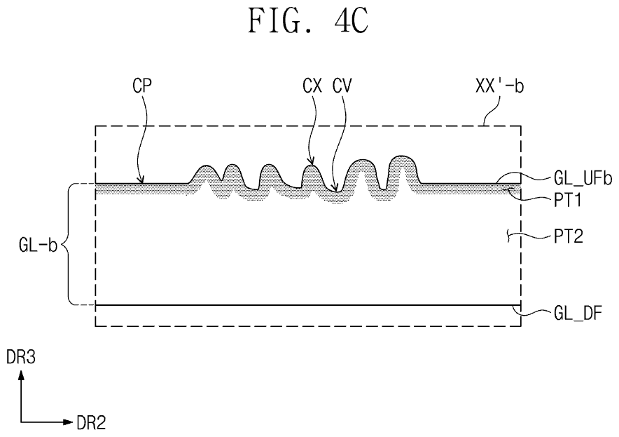

FIG. 4A is an enlarged cross-sectional view illustrating region XX′ of FIG. 3. FIG. 4A may be a cross-sectional view illustrating a window GL according to an embodiment.

Referring to FIG. 4A, a lower surface GL_DF of the window GL may be flat. An upper surface GL_UF of the window GL may not be flat. The upper surface GL_UF of the window GL may include a convex portion CX and a concave portion CV. The convex portion CX and the concave portion CV may have an integral shape.

The convex portion CX may be a portion protruding toward a direction of getting closer to the display surface ES (see FIG. 1) in the thickness direction DR3. The convex portion CX may be a portion protruding upward, and in this case, the term “upward” may mean a direction parallel to a direction in which the third direction axis DR3 extends. The concave portion CV may be a portion recessed toward a direction of getting closer to the display surface ES (see FIG. 1) in the thickness direction DR3. The concave portion CV may be a portion recessed upward, and in this case, the term “upward” may mean a direction parallel to a direction in which the third direction axis DR3 extends.

The convex portion CX and the concave portion CV may each be formed in plurality. The plurality of convex portions CX and the plurality of concave portions CV may be repeatedly disposed in the transmission region TA (see FIG. 3). On a plane, the areas of the plurality of convex portions CX and the plurality of concave portions CV may be substantially the same as the area of the transmission region TA (see FIG. 3). Alternatively, on a plane, the areas of the plurality of convex portions CX and the plurality of concave portions CV may also be smaller than the area of the transmission region TA (see FIG. 3). In some aspects, the plurality of convex portions CX and/or the plurality of concave portions CV may be disposed also in the bezel region BZA (see FIG. 3). FIG. 4A illustrates that the convex portion CX and the concave portion CV are alternately disposed, but embodiments of the present disclosure are not limited thereto. For example, a flat portion may also be provided between the convex portion CX and the concave portion CV.

The plurality of convex portions CX and the plurality of concave portions CV may each have a non-uniform shape. The plurality of convex portions CX may have different heights. In this case, the term “height” means a length from a predetermined first plane to the highest point of the convex portion CX, that is, a length parallel to the thickness direction DR3. The plurality of concave portions CV may have different depths. In this case, the term “depth” means a length from the predetermined second plane to the lowest point of the concave portion CV, that is, a length parallel to the thickness direction DR3.

The window GL including the convex portion CX and the concave portion CV may have a surface roughness (Ra) ranging from about 10 nm to about 1000 nm. In this specification, the surface roughness is measured by using an atomic force microscopy (AFM). For example, the window GL may have a surface roughness ranging from about 25 nm or about 800 nm. The window having a surface roughness of less than about 10 nm may not reduce regular reflection light, and the window having a surface roughness of greater than about 1000 nm has deteriorated durability. On the contrary, since the window GL according to an embodiment has a surface roughness ranging from about 10 nm to about 1000 nm, the window GL may exhibit an excellent anti-glare property due to reduction in regular reflection light while achieving excellent durability.

The window GL according to an embodiment is formed through a later-described window manufacturing method according to an embodiment, and the window manufacturing method according to an embodiment may include steps of: providing heat; providing water; and performing an etching. The window GL formed through the window manufacturing method according to an embodiment which includes the steps described herein may have a surface roughness ranging from about 10 nm to about 1000 nm. The window GL formed through the window manufacturing method according to an embodiment which includes the steps of providing heat and water may have a nanoscale surface roughness

The window GL is a single-layered glass substrate, and the glass substrate may include SiO₂. The window GL may include one portion PT1 and the other portion PT2. In the window GL, the other portion PT2 may be a portion except for the portion PT1. The portion PT1 and the other portion PT2 have a difference in a concentration of silicon, and may be separated in the thickness direction DR3. In the window GL, the portion PT1 may be formed on the other portion PT2. The portion PT1 may include the upper surface GL_UF of the window GL. On a plane, the area of the portion PT1 may be smaller than or substantially the same as the area of the upper surface GL_UF of the window GL. For example, on a plane, the area of the portion PT1 may be smaller than or substantially the same as the area of the transmission region TA (see FIG. 3).

The portion PT1 may be spaced apart from the lower surface GL_DF of the window GL. The other portion PT2 may include the lower surface GL_DF of the window GL. The first concentration of silicon in the portion PT1 may be higher than the second concentration of silicon in the other portion PT2. The portion PT1 in which silicon has a relatively high concentration may exhibit a low refractive index characteristic. The portion PT1 in which silicon has a relatively high concentration may be a silicon rich portion. The first concentration of silicon may mean a concentration of silicon in the portion PT1 with respect to the total content of the portion PT1. The second concentration of silicon may mean a concentration of silicon in the other portion PT2 with respect to the total content of the other portion PT2.

The window GL is formed by performing a manufacturing process (that is, the window manufacturing method according to an embodiment) on a mother glass substrate, and the mother glass substrate may include sodium oxide (Na₂O), potassium oxide (K₂O), lithium oxide (Li₂O), magnesium oxide (MgO), calcium oxide (CaO), silicon dioxide (SiO₂), or the like. The mother glass substrate means a glass substrate in a state before the manufacturing process is performed. In an example in which the later-described window manufacturing method according to an embodiment is performed, a metal cation (that is, Na⁺, K⁺, Li⁺, Mg²⁺, and Ca²⁺) of each of Na₂O, K₂O, Li₂O, MgO, and CaO is eluted (released) from the mother glass substrate, and the portion PT1 may have a relatively smaller amount of cations than the other portion PT2. Accordingly, the first concentration of silicon in the portion PT1 may be higher than the second concentration of silicon in the other portion PT2. For example, the first concentration of the silicon in the portion PT1 may be about 90% to about 95%, or about 99% or more.

The upper surface GL_UF of the window GL may be a surface onto which light is incident from the outside. As a concentration of silicon in the portion PT1 including the upper surface GL_UF is relatively high, the portion PT1 has a low refractive index, and thus the window GL may exhibit an excellent anti-reflection property. The portion PT1 in which the concentration of the silicon is relatively high may have a thickness T1 ranging from about 20 nm to about 200 nm. The thickness T1 of the portion PT1 may indicate a depth measured from the upper surface GL_UF as a starting point. For example, the portion PT1 may have a thickness T1 of about 100 μm. A window, which includes one portion having a thickness of less than about 20 nm, does not exhibit an anti-reflection property, and a window which includes one portion having a thickness of greater than about 200 nm has reduced durability. On the contrary, the window GL including the portion PT1, in which silicon has a relatively high concentration and which has a thickness T1 ranging from about 20 nm to about 200 nm, may exhibit an excellent anti-reflection property and durability.

FIGS. 4B and 4C are cross-sectional views illustrating region XX′ according to other embodiments. Hereinafter, with regard to the descriptions of FIGS. 4B and 4C, the contents duplicated with those described with the references to FIGS. 1 to 4A will not be explained again, and the following description will be mainly focused on the differences.

Compared to the window GL of region XX′ illustrated in FIG. 4A, a window GL-a of region XX′-a illustrated in FIG. 4B differs from the window GL in that a lower surface GL_DFa is not flat. Referring to FIG. 4B, the lower surface GL_DFa of the window GL-a may include a sub-convex portion CX-a and a sub-concave portion CV-a. The sub-convex portion CX-a and the sub-concave portion CV-a may have an integral shape.

The sub-convex portion CX-a may be a portion protruding toward a direction of getting closer to the display surface ES (see FIG. 1) in the thickness direction DR3. The sub-convex portion CX-a may be a portion protruding upward, and in this case, the term “upward” may mean a direction parallel to a direction in which the third direction axis DR3 extends. The sub-concave portion CV-a may be a portion recessed toward a direction of getting closer to the display surface ES (see FIG. 1) in the thickness direction DR3. The sub-concave portion CV-a may be a portion recessed upward, and in this case, the term “upward” may mean a direction parallel to a direction in which the third direction axis DR3 extends.

The sub-convex portion CX-a and the sub-concave portion CV-a may each be formed in plurality. The plurality of sub-convex portions CX-a and the plurality of sub-concave portions CV-a may be repeatedly disposed in the transmission region TA (see FIG. 3). In some aspects, the plurality of sub-convex portions CX-a and/or the plurality of sub-concave portions CV-a may be disposed also in the bezel region BZA (see FIG. 3).

The plurality of sub-convex portions CX-a and the plurality of sub-concave portions CV-a may each have a non-uniform shape. The plurality of sub-convex portions CX-a may have different heights. In this case, the term “height” means a length from a predetermined third plane to the highest point of the sub-convex portions CX-a, that is, a length parallel to the thickness direction DR3. The plurality of sub-concave portions CV-a may have different depths. In this case, the term “depth” means a length from the predetermined second plane to the lowest point of the sub-concave portion CV-a, that is, a length parallel to the thickness direction DR3.

In the window GL-a, the lower surface GL_DFa and the upper surface GL_UF may not have a symmetrical shape. The convex portion CX of the upper surface GL_UF and the sub-convex portion CX-a of the lower surface GL_DFa may not have a symmetrical shape. The concave portion CV of the upper surface GL_UF and the sub-concave portion CV-a of the lower surface GL_DFa may not have a symmetrical shape.

Compared to the window GL of region XX′ illustrated in FIG. 4A, a window GL-b of region XX′-b illustrated in FIG. 4C differs from the window GL in that an upper surface GL_UFb includes a flat portion CP. Referring to FIG. 4C, the upper surface GL_UFb of the window GL-b may include a convex portion CX, a concave portion CV, and the flat portion CP. The flat portion CP is flat and may be substantially parallel to the lower surface GL_DF. The convex portion CX, the concave portion CV, and the flat portion CP may have an integral shape. The convex portion CX and the concave portion CV are formed in one region of the upper surface GL_UFb, and the other region of the upper surface GL_UFb except the one region may be the flat portion CP. The flat portion CP may be disposed on both sides of the one region in which the convex portion CX and the concave portion CV are formed. For example, on a plane, the flat portion CP may be disposed so as to surround the one region in which the convex portion CX and the concave portion CV are formed. However, this is presented as an example, and embodiments of the present disclosure are not limited thereto.

FIG. 5 is a cross-sectional view illustrating a portion taken along line I-I′ of FIG. 2. FIG. 5 may be a cross-sectional view illustrating, in detail, an active region DM-AA of the display module DM.

Referring to FIG. 5, a display module DM may include a display panel DP and an input-sensing part TP disposed on the display panel DP. The display panel DP may be configured to substantially generate an image. The input-sensing part TP may be disposed on the display panel DP. The input-sensing part TP may be directly disposed on an encapsulation layer TFE. Alternatively, an adhesive member may also be disposed between the input-sensing part TP and the display panel DP.

In this specification, when an element is referred to as being directly disposed/provided/formed on another element, there are no intervening elements therebetween. That is, the wording, “an element is ‘directly disposed/provided/formed on’ another element” means that an element is ‘in contact with’ another element.

The input-sensing part TP may detect an external input, change the detected external input to a predetermined input signal, and provide the input signal to the display panel DP. For example, the input-sensing part TP may be a touch-sensing part which detects a touch. The input-sensing part TP may recognize a direct touch by a user, an indirect touch by a user, a direct touch by an object, an indirect touch by an object, or the like.

The input-sensing part TP may detect at least one of a position or intensity (pressure) of a touch applied from the outside. In an embodiment, the input-sensing part TP may have various structures or be composed of various materials, but is not limited to any one embodiment. For example, the input-sensing part TP may detect an external input in a capacitive manner. The display panel DP may receive the input signal from the input-sensing part TP and generate an image corresponding to the input signal.

The display panel DP may include a base substrate BS, a circuit layer DP-CL, a display element layer DP-EL, and the encapsulation layer TFE, which are sequentially stacked. Additional or alternative to the example illustrated, an additional member may also be further disposed between two adjacent layers among the base substrate BS, the circuit layer DP-CL, the display element layer DP-EL, and the encapsulation layer TFE.

The base substrate BS may provide a base surface on which the circuit layer DP-CL is disposed. The base substrate BS may be a flexible substrate which is bendable, foldable, rollable, or the like. The base substrate BS may be a glass substrate, a metal substrate, a polymer substrate, or the like. However, embodiments of the present disclosure are not limited thereto, and the base substrate BS may include an inorganic layer, an organic layer, or a composite material layer.

The base substrate BS may include a single layer or a plurality of layers. For example, the base substrate BS may include a first synthetic resin layer, a multi- or single-layered inorganic layer, or a second synthetic resin layer disposed on the multi- or single-layered inorganic layer. The first synthetic resin layer and the second synthetic resin layer may each include a polyimide-based resin. In some aspects, the first synthetic resin layer and the second synthetic resin layer may each include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “˜˜” based resin is considered as including a functional group of “˜˜”.

The display panel DP may include a transistor TR and a light-emitting element ED. The transistor TR and the light-emitting element ED may be disposed on the base substrate BS. FIG. 5 illustrates one transistor TR, but the display panel DP may substantially include at least one capacitor and a plurality of transistors for driving the light-emitting element ED.

The circuit layer DP-CL may include an insulating layer, a semiconductor pattern, a conductive pattern, a signal line, or the like. For example, the circuit layer DP-CL may include a switching transistor or a driving transistor for driving the light-emitting element ED of the display element layer DP-EL.

The circuit layer DP-CL may include a shielding electrode BML, the transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stacked structure of the circuit layer DP-CL illustrated in FIG. 5 is presented as an example, and a stacked structure of the circuit layer DP-CL may be changed according to a configuration of the display panel DP and processes for the circuit layer DP-CL, or other configurations or processes as supported by the present disclosure.

The shielding electrode BML may be disposed on the base substrate BS. The shielding electrode BML may overlap the transistor TR. The shielding electrode BML may block light incident onto the transistor TR from below the display panel DP to protect the transistor TR. The shielding electrode BML may include a conductive material. In an example in which a voltage is applied to the shielding electrode BML, a threshold voltage of the transistor TR disposed on the shielding electrode BML may be maintained. However, embodiments of the present disclosure are not limited thereto, and the shielding electrode BML may be a floating electrode. The shielding electrode BML may also be omitted.

The buffer layer BFL may be disposed on the base substrate BS and cover the shielding electrode BML. The buffer layer BFL may include an inorganic layer. The buffer layer BFL may improve a bonding force between the base substrate BS and a semiconductor pattern or a conductive pattern, which is disposed on the buffer layer BFL.

The transistor TR may include a source S1, a channel C1, a drain D1, and a gate G1. The source S1, the channel C1, and the drain D1 of the transistor TR may be formed from a semiconductor pattern. The semiconductor pattern of the transistor TR may include polysilicon, amorphous silicon, or a metal oxide. However, any material having semiconductor properties may be applied without limitation, and is not limited to any one embodiment.

The semiconductor pattern may include a plurality of regions divided according to a conductivity level. In the semiconductor pattern, a region, which is doped with a dopant or in which a metal oxide is reduced, may have a high conductivity, and may serve substantially as a source electrode and a drain electrode of the transistor TR. A highly conductive region of the semiconductor pattern may correspond to the source S1 and the drain D1 of the transistor TR. In the semiconductor pattern, a region, which is undoped or lightly doped or which has a low conductivity due to a non-reduced metal oxide, may correspond to the channel C1 (or active) of the transistor TR.

The first insulating layer INS1 may cover the semiconductor pattern of the transistor TR and be disposed on the buffer layer BFL. The gate G1 of the transistor TR may be disposed on the first insulating layer INS1. On a plane, the gate G1 may overlap the channel C1 of the transistor TR. The gate G1 may function as a mask during the process of doping the semiconductor pattern of the transistor TR.

The second insulating layer INS2 may cover the gate G1 and be disposed on the first insulating layer INS1. The third insulating layer INS3 may be disposed on the second insulating layer INS2.

The connection electrode CNE may include a first connection electrode CNE1 and a second connection electrode CNE2 which electrically connect the transistor TR and the light-emitting element ED. However, a configuration of the connection electrode CNE which electrically connects the transistor TR to the light-emitting element ED is not limited thereto. Either of the first connection electrode CNE1 or the second connection electrode CNE2 may be omitted, or an additional connection electrode may be further included.

The first connection electrode CNE1 may be disposed on the third insulating layer INS3. The first connection electrode CNE1 may be connected to the drain D1 via a first contact hole CH1 passing through the first to third insulating layers INS1 to INS3. The fourth insulating layer INS4 may cover the first connection electrode CNE1 and be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 via a second contact hole CH2 passing through the fourth and fifth insulating layers INS4 and INS5. The sixth insulating layer INS6 may cover the second connection electrode CNE2 and be disposed on the fifth insulating layer INS5.

The first to sixth insulating layers INS1 to INS6 may each include an inorganic layer or an organic layer. For example, the inorganic layer may include at least one of aluminum oxide, titanium oxide, silicon oxide, silicon oxynitride, zirconium oxide, or hafnium oxide. The organic layer may also include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer DP-EL may include a pixel-defining film PDL and the light-emitting element ED. The light-emitting element ED may include a first electrode AE, a second electrode CE disposed on the first electrode AE, and a light-emitting layer EML disposed between the first electrode AE and the second electrode CE. In some aspects, the light-emitting element ED may further include a hole control layer HCL and an electron control layer TCL. The hole control layer HCL may be disposed between the first electrode AE and the light-emitting layer EML. The electron control layer TCL may be disposed between the light-emitting layer EML and the second electrode CE.

The light-emitting element ED may emit light. For example, the light-emitting element ED may include an organic light-emitting material, an inorganic light-emitting material, an organic-inorganic light-emitting material, quantum dots, or quantum rods. For example, the light-emitting element ED may include a micro LED, or a nano LED.

The first electrode AE may be disposed on the sixth insulating layer INS6. The first electrode AE may be connected to the second connection electrode CNE2 via a third contact hole CH3 passing through the sixth insulating layer INS6. The first electrode AE may be electrically connected to the drain D1 of the transistor TR via the first and second connection electrodes CNE1 and CNE2.

The first electrode AE may be formed of a metal material, a metal alloy, or a conductive compound. The first electrode AE may be an anode or a cathode. However, embodiments of the present disclosure are not limited thereto. In some aspects, the first electrode AE may be a pixel electrode. The first electrode AE may be a transmissive electrode, a transflective electrode, or a reflective electrode. The first electrode AE may include: at least one selected from among Ag, Mg, Cu, Al, Pt, Pd, Au, Ni, Nd, Ir, Cr, Li, Ca, LiF, Mo, Ti, W, In, Sn, and Zn; a compound of two or more materials selected from thereamong; a mixture of two or more materials selected from thereamong; or oxides thereof.

When the first electrode AE is the transmissive electrode, the first electrode AE may include a transparent metal oxide, for example, indium tin oxide (ITO), indium zinc oxide (IZO), zinc oxide (ZnO), indium tin zinc oxide (ITZO), etc. In an example in which the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (for example, a mixture of Ag and Mg). Alternatively, the first electrode AE may have a multi-layered structure including a reflective film or a transflective film, which is formed of the materials described herein, and a transparent conductive film formed of indium tin oxide (ITO), indium zinc oxide (IZO), zinc oxide (ZnO), indium tin zinc oxide (ITZO), or the like. For example, the first electrode AE may have a three-layered structure of ITO/Ag/ITO, but is not limited thereto. Embodiments of the present disclosure are not limited thereto, and the first electrode AE may include the metal materials described herein, a combination of two or more metal materials selected from thereamong, oxides of the metal materials described herein, or the like.

The pixel-defining film PDL may be disposed on the sixth insulating layer INS6. A light-emitting opening PX_OP which exposes a portion of the first electrode AE may be defined in the pixel-defining film PDL. A portion, of the first electrode AE, which is exposed by the light-emitting opening PX_OP may be defined as a light-emitting region LA.

An active region DM-AA of the display module DM may include the light-emitting region LA and a light-blocking region NLA. A region, in which the pixel-defining film PDL is disposed, may correspond to the light-blocking region NLA. The light-blocking region NLA may surround the light-emitting region LA within the active region DM-AA.

The hole control layer HCL may be disposed on the first electrode AE and the pixel-defining film PDL. The hole control layer HCL may be provided as a common layer overlapping the light-emitting region LA and the light-blocking region NLA. Additional or alternative to the example illustrated, the hole control layer HCL may also be disposed in a region corresponding to the light-emitting opening PX_OP. The hole control layer HCL may include at least one of a hole transport layer, a hole injection layer, or an electron blocking layer. The hole control layer HCL may include a typical hole injection material and/or a typical hole transport material.

The light-emitting layer EML may be disposed on the hole control layer HCL. The light-emitting layer EML may be disposed in a region corresponding to the light-emitting opening PX_OP. Alternatively, the light-emitting layer EML may also be provided as a common layer. The light-emitting layer EML may include an organic light-emitting material and/or an inorganic light-emitting material. The light-emitting layer EML may emit light having one color of red, green, or blue. For example, the light-emitting layer EML may emit blue color light.

The electron control layer TCL may be disposed on the light-emitting layer EML. The electron control layer TCL may be provided as a common layer overlapping the light-emitting region LA and the light-blocking region NLA. Additional or alternative to the example illustrated, the electron control layer TCL may also be disposed in a region corresponding to the light-emitting opening PX_OP. The electron control layer TCL may include at least one of an electron transport layer, an electron injection layer, or a hole blocking layer. The electron control layer TCL may include a typical electron injection material and/or a typical electron transport material.

The second electrode CE may be disposed on the electron control layer TCL. The second electrode CE may be provided as a common layer overlapping the light-emitting region LA and the light-blocking region NLA. The second electrode CE may be a common electrode. The second electrode CE may be a cathode or an anode but embodiments of the present disclosure are not limited thereto. In an example in which the first electrode AE is an anode, the second electrode CE may be a cathode, and when the first electrode AE is a cathode, the second electrode CE may be an anode.

The second electrode CE may be a transmissive electrode, a transflective electrode, or a reflective electrode. In an example in which the second electrode CE is the transmissive electrode, the second electrode CE may include a transparent metal oxide, for example, indium tin oxide (ITO), indium zinc oxide (IZO), zinc oxide (ZnO), indium tin zinc oxide (ITZO), or the like.

When the second electrode CE is the transflective electrode or the reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (for example, AgMg, AgYb, or MgYb). Alternatively, the second electrode CE may have a multi-layered structure including a reflective film or a transflective film, which is formed of the materials described herein, and a transparent conductive film formed of indium tin oxide (ITO), indium zinc oxide (IZO), zinc oxide (ZnO), indium tin zinc oxide (ITZO), or the like. For example, the second electrode CE may include the metal materials described herein, a combination of two or more metal materials selected from thereamong, oxides of the metal materials described herein, or the like.

The encapsulation layer TFE may be disposed on the display element layer DP-EL. The encapsulation layer TFE may be disposed on the second electrode CE and cover the light-emitting element ED. The encapsulation layer TFE may protect the display element layer DP-EL against moisture, oxygen, and/or foreign substances such as, for example, dust particles. The encapsulation layer TFE may include a plurality of thin films.

The encapsulation layer TFE may include at least one inorganic film. For example, the encapsulation layer TFE may include inorganic films disposed on the second electrode CE, and an organic film disposed between the inorganic films. The inorganic film may protect the light-emitting element ED against moisture/oxygen, and the organic film may protect the light-emitting element ED against foreign substances such as, for example, dust particles.

The input-sensing part TP may be disposed on the display panel DP. For example, the input-sensing part TP may be directly disposed on the encapsulation layer TFE of the display panel DP. Alternatively, an adhesive layer may also be disposed between the input-sensing part TP and the display panel DP.

The input-sensing part TP may include a first sensing-insulating layer IL1, a second sensing-insulating layer IL2, and a third sensing-insulating layer IL3. The input-sensing part TP may include at least one conductive layer disposed on the sensing-insulating layers. The input-sensing part TP may include a first conductive layer CDL1 and a second conductive layer CDL2.

The first sensing-insulating layer IL1 may be disposed on the encapsulation layer TFE. The first sensing-insulating layer IL1 may include at least one inorganic insulating layer. The first sensing-insulating layer IL1 may be in contact with the encapsulation layer TFE. Alternatively, the first sensing-insulating layer IL1 may also be omitted, and in this case, the first conductive layer CDL1 may be in contact with the encapsulation layer TFE.

The first conductive layer CDL1 may be disposed on the first sensing-insulating layer IL1. The first conductive layer CDL1 may include a plurality of first conductive patterns. The plurality of first conductive patterns may be disposed on the first sensing-insulating layer IL1. The second sensing-insulating layer IL2 may be disposed on the first sensing-insulating layer IL1 so as to cover at least a portion of the first conductive layer CDL1.

The second conductive layer CDL2 may be disposed on the second sensing-insulating layer IL2. The second conductive layer CDL2 may include a plurality of second conductive patterns. The plurality of second conductive patterns may be disposed on the second sensing-insulating layer IL2. The plurality of second conductive patterns may be respectively connected to the plurality of first conductive patterns via a contact hole formed in the second sensing-insulating layer IL2.

The plurality of first conductive patterns of the first conductive layer CDL1 and the plurality of second conductive patterns of the second conductive layer CDL2 may each be disposed to correspond to the light-blocking region NLA. The plurality of first conductive patterns of the first conductive layer CDL1 and the plurality of second conductive patterns of the second conductive layer CDL2 may each be a mesh pattern.

The third sensing-insulating layer IL3 may be disposed on the second sensing-insulating layer IL2 and cover the second conductive layer CDL2. The second sensing-insulating layer IL2 and the third sensing-insulating layer IL3 may each include an inorganic insulating layer or an organic insulating layer.

The first conductive layer CDL1 and the second conductive layer CDL2 may each have a single-layered structure or a multi-layered structure in which layers are stacked along the third direction DR3. The conductive layers CDL1 and CDL2 having a single-layered structure may each include a metal layer or a transparent conductive layer. The metal layer may include molybdenum, silver, titanium, copper, aluminum, or an alloy thereof. The transparent conductive layer may include transparent conductive oxides such as, for example, an indium tin oxide (ITO), an indium zinc oxide (IZO), a zinc oxide (ZnO), and an indium tin zinc oxide (ITZO). In some aspects, the transparent conductive layer may include a conductive polymer such as, for example, PEDOT, a metal nanowire, graphene, or the like.

The conductive layers CDL1 and CDL2 having a multi-layered structure may include metal layers. For example, the metal layers may have a three-layered structure of titanium (Ti)/aluminum (Al)/titanium (Ti). The conductive layers CDL1 and CDL2 having a multi-layered structure may include at least one metal layer and at least one transparent conductive layer.

FIGS. 6A to 6D, and 7 are views illustrating an electronic apparatus EA-a according to another embodiment of the inventive concept. Hereinafter, with regard to the descriptions of FIGS. 6A to 6D, and 7, the contents duplicated with those described with the references to FIGS. 1 to 5 will not be explained again, and the following description will be mainly focused on the differences.

The electronic apparatus EA-a illustrated in each of FIGS. 6A to 6D, and 7 may be an apparatus which is foldable with respect to at least one among folding axes FX1 and FX2. FIG. 6A is a perspective view illustrating the electronic apparatus EA-a in an unfolded state.

The electronic apparatus EA-a may include a first display surface FS and a second display surface RS. The first display surface FS may include a first display region F-DA, a first non-display region F-NDA, and a sub-region MH-a. The second display surface RS may be defined as a surface opposed to at least a portion of the first display surface FS. That is, the second display surface RS may be defined as a portion of a rear surface of the electronic apparatus EA-a.

The first display region F-DA may be activated in response to an electrical signal. The first display region F-DA may be a region in which an image IM may be displayed and various types of external inputs may be detected. The first non-display region F-NDA may be adjacent to the first display region F-DA. The light transmittance of the first non-display region F-NDA may be smaller than the light transmittance of the first display region F-DA. The first non-display region F-NDA may have a predetermined color. The first non-display region F-NDA may surround the first display region F-DA. Accordingly, a shape of the first display region F-DA may be substantially defined by the first non-display region F-NDA. However, this is presented as an example, and the first non-display region F-NDA may be disposed adjacent to a single side of the first display region F-DA as well as be omitted.

The sub-region MH-a may detect an external subject received via display surfaces FS and RS, or provide a sound signal, such as, for example, voice, to the outside via the display surfaces FS and RS. An optical signal such as, for example, visible light or infrared light may move to the sub-region MH-a.

Various electronic modules ELM (see FIG. 7) may be disposed so as to correspond to the sub-region MH-a. For example, the electronic module ELM (see FIG. 7) may include at least one of a camera, a speaker, a light detection sensor, or a heat detection sensor. The electronic apparatus EA-a may include the electronic module ELM (see FIG. 7) which captures an external image by using visible light passing through the sub-region MH-a or determines whether an external object is approaching by using infrared light.

The sub-region MH-a may be disposed within the first display region F-DA. However, this is presented as an example, and an arrangement of the sub-region MH-a is not limited to any one embodiment. For example, the sub-region MH-a may not only be surrounded by the first non-display region F-NDA but also be surrounded by the first display region F-DA and the first non-display region F-NDA. FIG. 6A and other figures herein illustrate one sub-region MH-a, but the sub-region MH-a may also be provided in plurality.

The electronic apparatus EA-a may include at least one folding region FA, and a plurality of non-folding regions NFA1 and NFA2 extending from the folding region FA. For example, a first non-folding region NFA1, the folding region FA, and a second non-folding region NFA2 may be defined along the second direction DR2. The electronic apparatus EA-a may include the first non-folding region NFA1 and the second non-folding region NFA2 which are spaced apart from each other in the second direction DR2, with the folding region FA between the first non-folding region NFA1 and the second non-folding region NFA2. For example, the first non-folding region NFA1 may be disposed on one side of the folding region FA along the second direction DR2, and the second non-folding region NFA2 may be disposed on the other side of the folding region FA along the second direction DR2.

FIG. 6A and other figures herein illustrate the electronic apparatus EA-a, according to an embodiment, including one folding region FA, but embodiments of the present disclosure are not limited thereto. A plurality of folding regions may be defined in the electronic apparatus EA-a. For example, the electronic apparatus according to an embodiment may include two or more folding regions, and may include three or more non-folding regions disposed with each of the folding regions therebetween.

FIG. 6B is a perspective view illustrating a folding operation of the electronic apparatus EA-a illustrated in FIG. 6A. FIG. 6C is a plan view illustrating a state in which the electronic apparatus EA-a illustrated in FIG. 6A is folded. FIG. 6D is a perspective view illustrating a folding operation of the electronic apparatus EA-a illustrated in FIG. 6A.

Referring to FIG. 6B, the electronic apparatus EA-a may be folded with respect to a first folding axis FX1 extending in the first direction DR1. In a folded state of the electronic apparatus EA-a, the folding region FA may have a predetermined curvature and radius of a curvature. The electronic apparatus EA-a may be folded with respect to the first folding axis FX1, and be changed into an in-folded state such that the first non-folding region NFA1 and the second non-folding region NFA2 face each other and the first display surface FS is not exposed to the outside.

FIG. 6C may be a plan view illustrating a state in which the electronic apparatus EA-a is in-folded. Referring to FIG. 6C, in an in-folded state of the electronic apparatus EA-a, the second display surface RS may be viewed by a user. In this case, the second display surface RS may include a second display region R-DA which displays an image. The second display region R-DA may be activated in response to an electrical signal. The second display region R-DA may be a region in which an image may be displayed and various types of external inputs may be detected.

In some aspects, the second display surface RS may include a second non-display region R-NDA. The second non-display region R-NDA may be adjacent to the second display region R-DA. The light transmittance of the second non-display region R-NDA may be smaller than the light transmittance of the second display region R-DA. The second non-display region R-NDA may have a predetermined color. The second non-display region R-NDA may surround the second display region R-DA. Although not illustrated, the electronic apparatus EA-a may further include, also in the second display surface RS, a sub-region in which an electronic module including various components is disposed, and is not limited to any one embodiment.

Referring to FIG. 6D, the electronic apparatus EA-a may be folded with respect to a second folding axis FX2 extending in the first direction DR1. The electronic apparatus EA-a may be folded with respect to the second folding axis FX2, and be changed into an out-folded state such that the first display surface FS is exposed to the outside. The electronic apparatus EA-a according to an embodiment may be configured to repeatedly perform an in-folding or out-folding operation from an unfolding operation and vice versa, but embodiments of the present disclosure are not limited thereto.

FIGS. 6A to 6D illustrate examples in which the electronic apparatus EA-a is folded with respect to one folding axis (FX1 or FX2), but in the electronic apparatus according to an embodiment, the number of folding axes and the number of non-folding regions corresponding to the number of folding axes are not particularly limited thereto. For example, the electronic apparatus EA-a may be folded with respect to a plurality of folding axes such that respective portions of the first display surface FS and the second display surface RS face each other. In some aspects, it is illustrated that the first and second folding axes FX1 and FX2 are parallel to a long side of the electronic apparatus EA-a, but embodiments of the present disclosure are not limited thereto. The first and second folding axes FX1 and FX2 may be parallel to a short side of the electronic apparatus EA-a.

In a state in which the electronic apparatus EA-a is folded as illustrated in FIG. 6C, the first non-folding region NFA1 and the second non-folding region NFA2 may be defined as portions having the display surfaces FS and RS parallel to a plane defined by the first direction axis DR1 and the second direction axis DR2, and the folding region FA may be defined as a region between the first non-folding region NFA1 and the second non-folding region NFA2. The folding region FA may have a curved portion which is curved so as to have a predetermined curvature in a folded state.

FIG. 7 is an exploded perspective view of the electronic apparatus EA-a illustrated in FIG. 6A. Referring to FIG. 7, the electronic apparatus EA-a may include a display device DD-a and an electronic module ELM. The electronic apparatus EA-a may further include a housing HAU and a protective layer PL. The display device DD-a may include a display module DM-a and a window member WD disposed on the display module DM-a. The window member WD may be folded with respect to the folding axes FX1 and FX2 (see FIGS. 6B and 6D).

The display module DM-a may include a folding display part FP-D and non-folding display parts NFP1-D and NFP2-D. The folding display part FP-D may be a portion corresponding to the folding region FA (see FIG. 6A), and the non-folding display parts NFP1-D and NFP2-D may be portions corresponding to the non-folding regions NFA1 and NFA2 (see FIG. 6A).

The folding display part FP-D may correspond to a portion which is folded with respect to the folding axes FX1 and FX2 (see FIGS. 6B and 6D). The non-folding display parts NFP1-D and NFP2-D may include a first non-folding display part NFP1-D and a second non-folding display part NFP2-D. The first non-folding display part NFP1-D and the second non-folding display part NFP2-D may be spaced apart from each other in the second direction DR2, with the folding display part FP-D between the first non-folding display part NFP1-D and the second non-folding display part NFP2-D. The first non-folding display part NFP1-D may be a portion corresponding to the first non-folding region NFA1 (see FIG. 6A). The second non-folding display part NFP2-D may be a portion corresponding to the second non-folding region NFA2 (see FIG. 6A).

Although not illustrated, the electronic apparatus EA-a may further include a lower module disposed below the display module DM-a. For example, the lower module may include a support layer, a cushion layer, a shielding layer, or the like. The support layer may be a thin-film metal substrate. The cushion layer may include an elastomer such as, for example, a sponge, a foam, or a urethane resin. The shielding layer may be an electromagnetic wave shielding layer or a heat dissipation layer. However, this is presented as an example, and components included in the lower module may vary according to a size, a shape or operating characteristics, or the like., of the electronic apparatus EA-a.

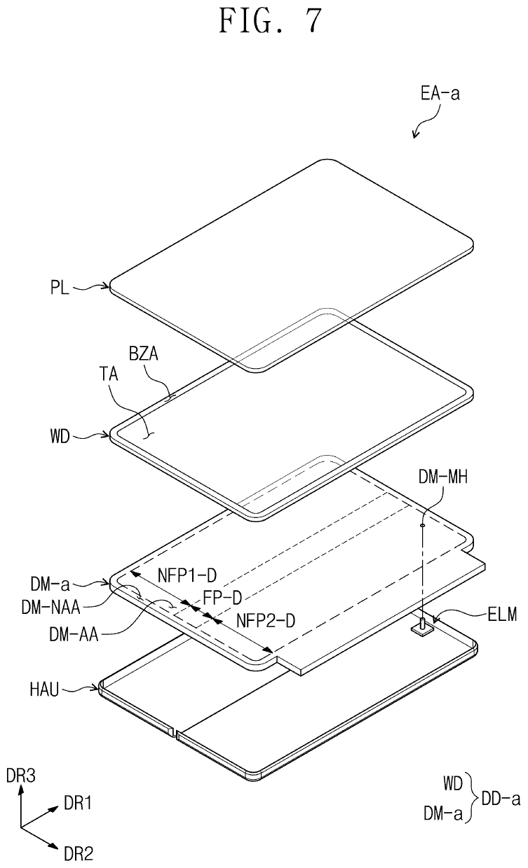

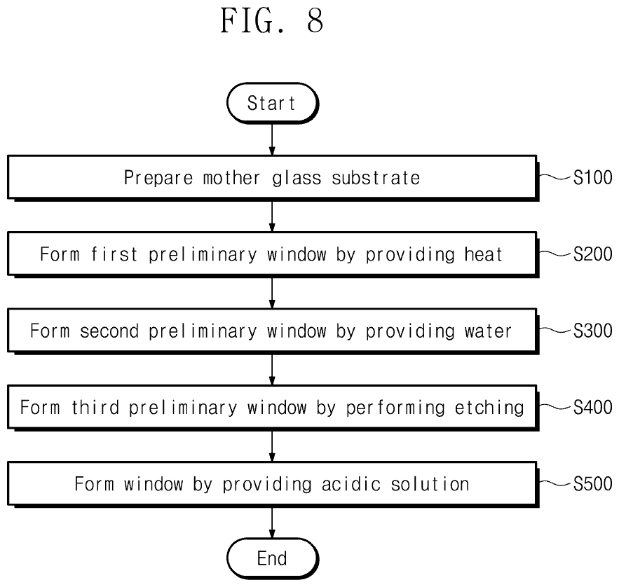

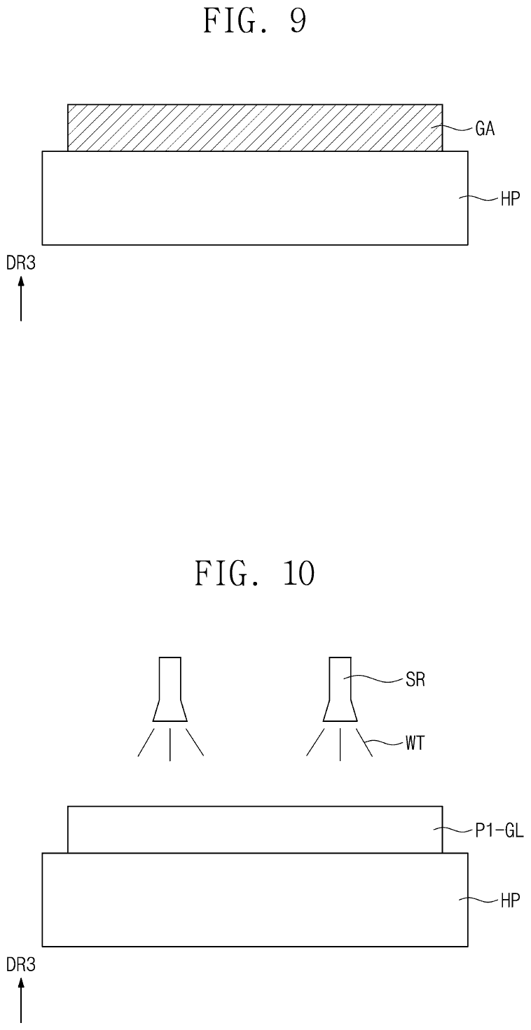

A window according to an embodiment may be formed through a window manufacturing method according to an embodiment. FIG. 8 is a flowchart illustrating a window manufacturing method according to an embodiment. FIGS. 9 to 12 are views schematically illustrating window manufacturing steps according to an embodiment. Hereinafter, with regard to the descriptions of FIGS. 8 to 12, the contents duplicated with those described with the references to FIGS. 1 to 7 will not be explained again, and the following description will be mainly focused on the differences.

In the descriptions of the window manufacturing method and processes herein, the operations may be performed in a different order than the order shown and/or described, or the operations may be performed in different orders or at different times. Certain operations may also be left out, one or more operations may be repeated, or other operations may be added. Descriptions that an element “may be disposed,” “may be formed,” and the like include methods, processes, and techniques for disposing, forming, and the like in accordance with example aspects described herein.

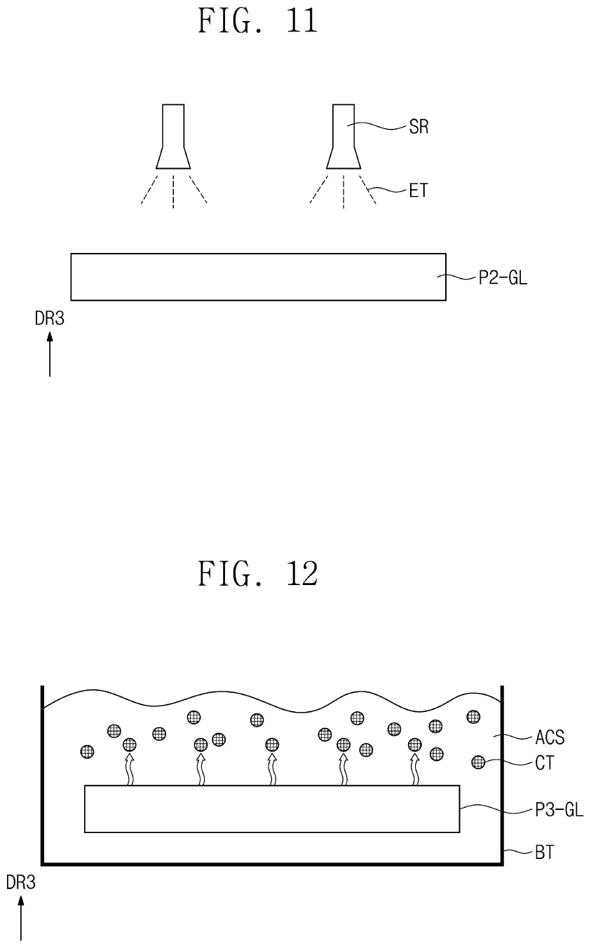

Referring to FIG. 8, the window manufacturing method according to an embodiment includes steps of: preparing a mother glass substrate (S100); forming a first preliminary window by providing heat (S200); forming a second preliminary window by providing water (S300); forming a third preliminary window by performing an etching (S400); and forming a window by providing an acidic solution (S500). A first preliminary window P1-GL (see FIG. 10) may be formed from a mother glass substrate GA (see FIG. 9), and a second preliminary window P2-GL (see FIG. 11) may be formed from the first preliminary window P1-GL (see FIG. 10). A third preliminary window P3-GL (see FIG. 12) may be formed from the second preliminary window P2-GL (see FIG. 11), and the windows GL, GL-a, and GL-b (see FIGS. 4A to 4C) each may be formed from the third preliminary window P3-GL (see FIG. 12).

FIG. 9 is a view illustrating the step of applying heat to the mother glass substrate GA. The mother glass substrate GA is a glass substrate before a manufacturing process is performed and may include SiO₂. The mother glass substrate GA may further include Na₂O, K₂O, Li₂O, MgO, CaO, or the like. The mother glass substrate GA may be used without limitation as long as the glass substrate is capable of forming the desired windows GL, GL-a, and GL-b (see FIGS. 4A to 4C) while including SiO₂.

Referring to FIG. 9, the mother glass substrate GA may be disposed on a hot plate HP. Heat from the hot plate HP may be applied to the mother glass substrate GA. However, this is presented as an example, and a method of applying heat to the mother glass substrate GA is not limited thereto.

In the step of applying heat to the mother glass substrate GA, the heat may have a temperature ranging from about 100° C. to about 200° C. In an example in which heat is applied to the mother glass substrate at a temperature of less than about 100° C., the window having a surface roughness of the desired degree (that is, about 10 nm to about 1000 nm) is not formed. In an example in which heat is applied to the mother glass substrate at a temperature of greater than about 200° C., the mother glass substrate is damaged due to a thermal shock. On the contrary, the window manufacturing method according to an embodiment may include the step of applying heat to the mother glass substrate GA in which the heat has a temperature ranging from about 100° C. to about 200° C., thereby exhibiting excellent processability and supporting the formation of the window GL having a surface roughness ranging from about 10 nm to about 1000 nm.

In an example in which heat applied to the mother glass substrate is a temperature of about 100° C., the window GL having a surface roughness of about 800 nm may be formed. Alternatively, when heat applied to the mother glass substrate has a temperature of about 200° C., the window GL having a surface roughness of about 25 nm may be formed.

The heat is applied to the mother glass substrate GA, such that a first preliminary window P1-GL illustrated in FIG. 10 may be formed. Referring to FIG. 10, water WT may be provided onto the first preliminary window P1-GL. The water WT may be provided from a providing apparatus SR, and the water WT may be provided onto the first preliminary window P1-GL through a spraying method. The water WT may provide ultra-pure water used for manufacturing a semiconductor.

The water WT is provided onto the first preliminary window P1-GL, such that a second preliminary window P2-GL illustrated in FIG. 11 may be formed. FIG. 11 illustrates a step of etching the second preliminary window P2-GL, and an etchant ET may be provided onto the second preliminary window P2-GL. The etchant ET may be provided from the providing apparatus SR. FIGS. 10 and 11 illustrate that the water WT and the etchant ET are provided from the same providing apparatus SR, but this is presented as an example. The water WT and the etchant ET may be provided from different providing apparatuses. The etchant ET may include at least one of hydrogen fluoride (HF), ammonium fluoride (NH₄F), or ammonium hydrogen fluoride (NH₄HF₂).

Micro cracks may be present on an upper surface of the second preliminary window P2-GL formed by providing the heat and the water WT (see FIG. 10). In an example in which the etchant ET is provided into the micro cracks, as illustrated in FIG. 4A, the convex portion CX (see FIGS. 4A to 4C) and the concave portion CV (see FIGS. 4A to 4C) may be formed. In an example in which the steps of providing heat and water are not performed, micro cracks are not present on the upper surface, and thus it is not easy to form the convex portion and the concave portion. Therefore, it is difficult to form the window having a nanoscale surface roughness. On the contrary, through at least the steps of providing the heat and the water on the mother glass substrate in accordance with one or more embodiments of the present disclosure, the window manufacturing method supports forming the windows GL, GL-a, and GL-b (see FIGS. 4A to 4C) having a surface roughness ranging from about 10 nm to about 1000 nm. The windows GL, GL-a, and GL-b (see FIGS. 4A to 4C) manufactured by the window manufacturing method according to an embodiment may exhibit an excellent anti-glare property.

The water ET is provided onto the second preliminary window P2-GL, and then a third preliminary window P3-GL illustrated in FIG. 12 may be formed. FIG. 12 may illustrate a step of providing an acidic solution ACS on the third preliminary window P3-GL. The acidic solution ACS is provided into a predetermined vessel BT, and the third preliminary window P3-GL may be immersed in the acidic solution ACS. Metal cations CT may be eluted from the third preliminary window P3-GL in an immersed state. The metal cations CT may include at least one of Na⁺, K⁺, Li⁺, Mg²⁺, or Ca²⁺. The Na⁺, K⁺, Li⁺, Mg²⁺, and Ca²⁺ may be derived from Na₂O, K₂O, Li₂O, MgO, and CaO included in the mother glass substrate GA (see FIG. 9). As the metal cations CT are eluted, the first concentration of the silicon in the portion PT1 (see FIGS. 4A to 4C) may become higher than the second concentration of the silicon in the other portion PT2 (see FIGS. 4A to 4C). In the windows GL, GL-a, and GL-b (see FIGS. 4A to 4C) formed by eluting the metal cations CT from the third preliminary window P3-GL, the first concentration of silicon in the portion PT1 (see FIGS. 4A to 4C) including the upper surfaces GL_UF and GL_UFb (see FIGS. 4A to 4C) may be higher than the second concentration of silicon in the other portion PT2 (see FIGS. 4A to 4C). Accordingly, the portion PT1 (see FIGS. 4A to 4C) exhibits a low refractive index property, and the window GL according to an embodiment which includes the portion PT1 (see FIGS. 4A to 4C) may exhibit an excellent anti-reflection property.

The acidic solution ACS may be provided in which the temperature of the acidic solution ACS ranges from about 40° C. to about 80° C. In an example in which an acidic solution is provided having a temperature of less than about 40° C., the elution of metal cations is insufficient, and thus the desired one portion (that is, a portion in which the silicon has a relatively high concentration) is not formed. In an example in which the acidic solution is provided having a temperature of greater than about 80° C., the metal cations are excessively eluted, which leads to a deterioration in the durability of the glass substrate. On the contrary, the window manufacturing method according to an embodiment may include the step of providing the acidic solution ACS in which the temperature of the acidic solution ACS ranges from about 40° C. to about 80° C., thereby exhibiting excellent processability.

The acidic solution ACS may be provided for a time period ranging from about 5 minutes to about 15 minutes. That is, the method may include exposing the third preliminary window P3-GL to the acidic solution (i.e., immersing the third preliminary window P3-GL in the acidic solution) for a time period of about 5 minutes to about 15 minutes. In an example in which the third preliminary window P3-GL is exposed to (i.e., immersed in) the acidic solution for less than about 5 minutes, the elution of metal cations is insufficient, and thus the desired one portion (that is, a portion in which the silicon has a relatively high concentration) is not formed. In an example in which the third preliminary window P3-GL is exposed to (i.e., immersed in) the acidic solution for greater than about 15 minutes, the glass substrate has a decreased transmittance. In an example in which the third preliminary window P3-GL is exposed to (i.e., immersed in) the acidic solution for greater than about 15 minutes, the third preliminary window P3-GL is exposed to the acidic solution for an extended period of time, and thus due to the elution of even substances inside the glass substrate (that is, a deep portion), the glass substrate has a decreased transmittance. On the contrary, the window manufacturing method according to an embodiment may include the step of exposing the third preliminary window P3-GL to the acidic solution ACS for a time period ranging from about 5 minutes to about 15 minutes, thereby exhibiting excellent processability.

The acidic solution ACS may include at least one of hydrochloric acid (HCl), nitric acid (HNO₃), or sulfuric acid (H₂SO₄). An acidic component may be contained in an amount ranging from about 20 wt % to about 80 wt % with respect to 100 wt % of the total weight of the acidic solution ACS. The acidic solution ACS includes a solvent and a solute dissolved in the solvent, and the solute may be an acidic solid particle. The solid particle may include, as an acidic component, at least one of hydrochloric acid, nitric acid, or sulfuric acid. The acidic solution is prepared by dissolving solid particles, which are acidic components, in a solvent (for example, water), and when the solid particles are contained in an amount of greater than about 80 wt %, the solid particles do not dissolve in the solvent. In an example in which the acidic component is contained in an amount of less than about 20 wt %, the elution of metal cations is insufficient, and thus the desired one portion (that is, a portion in which silicon has a relatively high concentration) is not formed. On the contrary, the window manufacturing method according to an embodiment may include the step of providing the acidic solution ACS which include the acidic component satisfying the weight range described herein, thereby exhibiting excellent processability.

The typical window includes a glass substrate and a plurality of optical elements disposed on the glass substrate. A plurality of optical members include an anti-glare layer and an anti-reflection layer. The anti-glare layer is formed by performing a physical/chemical treatment on a surface of a glass substrate (or a preliminary anti-glare layer) such that a convex portion and a concave portion are formed thereon, and the anti-reflection layer is formed by coating the glass substrate (or the preliminary anti-reflection layer) with a multi-layered thin film. Alternatively, a window including a glass substrate and optical elements is formed by laminating, on the glass substrate, an anti-glare layer/an anti-reflection layer formed from a preliminary anti-glare layer/a preliminary anti-reflection layer.

Physical/chemical treatments include a sand blasting/an etching treatment, but it is not easy to form the anti-glare layer having a nanoscale surface roughness and/or uniform quality only by performing the physical/chemical treatments. In some aspects, the physical treatment reduces strength of the glass substrate. During a process of the multi-layered thin film coating, a coating process is performed on the glass substrate multiple times, and the multiple coating processes include processes of vacuum deposition, sputtering, and/or a curing after wet coating, respectively. In this case, according to process conditions, physical properties of the glass substrate, such as, for example, strength of the glass substrate, are deteriorated. Furthermore, a change in the exterior, such as, for example, warping, occurs due to property differences between the layer formed through the coating process and the glass substrate. The process of forming a plurality of optical elements increases manufacturing costs.

In contrast, in the window manufacturing method according to an embodiment, the steps of applying heat to the mother glass substrate, providing water, and providing an etchant as performed may secure an anti-glare property. Subsequently, the step of providing an acidic solution as performed may secure an anti-reflection property. Accordingly, the window manufacturing method in accordance with one or more embodiments of the present disclosure supports manufacturing a single-layered window with excellent durability. Therefore, the single-layered window manufactured by the window manufacturing method according to an embodiment may exhibit the excellent durability while having the anti-glare and anti-reflection properties. In some aspects, the window manufacturing method according to an embodiment does not include a step of forming additional optical members, and thus manufacturing costs may be reduced.

FIG. 13 is a graph illustrating a transmittance evaluated according to a wavelength in windows of Examples and Comparative Examples. FIG. 13 is a graph illustrating measurement results obtained by using a spectrophotometer CM-3600d (manufactured by Konica Minolta, Inc.). The wavelength is in a wavelength range of about 360 nm to about 720 nm, that is, in a visible light wavelength range. FIG. 13 illustrates windows, according to Examples and Comparative Examples, which are formed by performing steps of providing heat, providing water, and providing an etchant in the same manner, and then varying whether an acidic solution is provided or varying the time for which the acidic solution is provided.

In FIG. 13, CX1 indicates the window, of Comparative Example, which is not provided with an acidic solution. The windows indicated by EX1 to EX3 and CX2 to CX4 are provided with an acidic solution, and the acidic solution was provided in which the temperature of the acidic solution was of about 60° C. EX1 to EX3 indicate the windows, of Examples, which are provided with an acidic solution for about 5 minutes, about 10 minutes, and about 15 minutes, respectively. That is, the windows indicated by EX1 to EX3 of Examples, are formed through a manufacturing method satisfying the time for which an acidic solution (that is, a time period ranging from about 5 minutes to about 15 minutes) according to an embodiment is provided. CX2 to CX4 indicate the windows, of Comparative Examples, which are provided with an acidic solution for about 20 minutes, about 25 minutes, and about 30 minutes, respectively.

Referring to FIG. 13, it may be seen that CX1 of Comparative Example illustrates the maximum transmittance of about 92%. Compared to CX1 of Comparative Example, it may be seen that EX1 to EX3 of Examples show relatively high transmittances. It may be seen that CX2 to CX4 of Comparative Examples show low transmittances adjacent to the transmittance of CX1 of Comparative Example in a wavelength range of about 420 nm to about 540 nm. CX2 to CX4 of Comparative Examples have reduced transmittances since an acidic solution is provided for greater than about 15 minutes. As described herein, the windows indicated by EX1 to EX3 of Examples are formed through the manufacturing method satisfying the time for which an acidic solution according to an embodiment is provided. Accordingly, it may be seen that the window formed through the window manufacturing method satisfying the time, for which an acidic solution according to an embodiment is provided, exhibits an excellent transmittance.

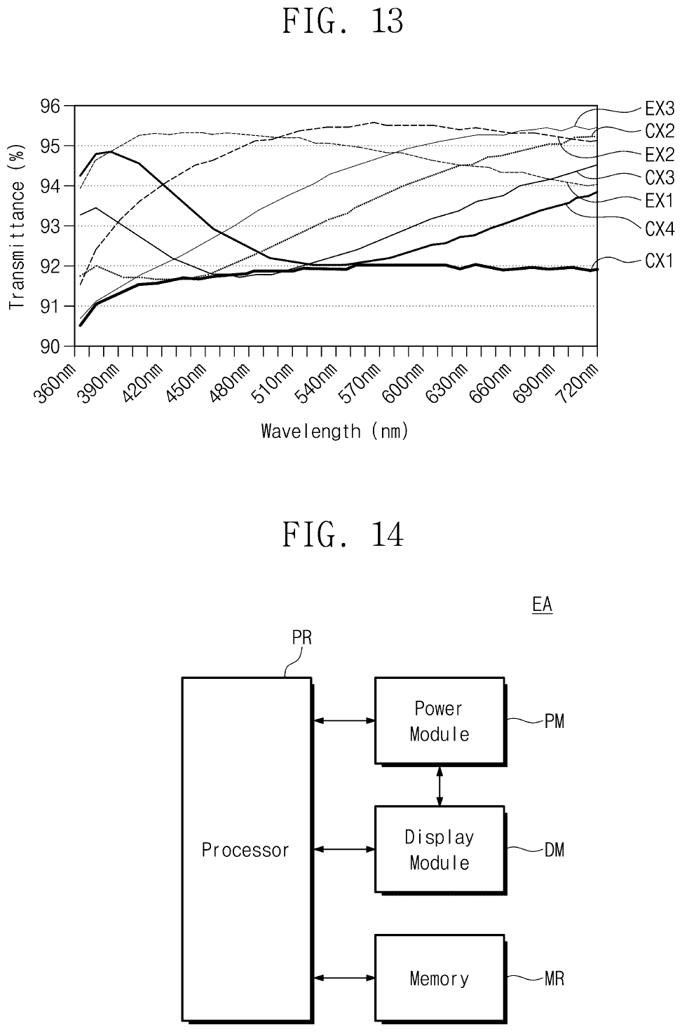

FIG. 14 is a block diagram of an electronic apparatus according to an embodiment. Referring to FIG. 14, an electronic apparatus EA according to an embodiment may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information required for the operation of the processor PR or the display module DM. When the processor PR executes an application stored in the memory MR, image data signals and/or input control signals are transmitted to the display module DM, and the display module DM may process the received signal and output image information through a display screen.

The power module PM may include a power supply module such as a power adapter or a battery device, and a power conversion module that converts power supplied by the power supply module to generate power required for the operation of the electronic apparatus EA.

At least one of the components of the electronic apparatus EA described above may be included in the display device according to the above-described embodiments. In addition, some of the individual modules functionally included in one module may be included in the display device, and others may be separately provided from the display device. For example, the display device may include a display module DM, and the processor PR, the memory MR and the power module PM may be provided in the form of other devices within the electronic apparatus EA, rather than the display device.

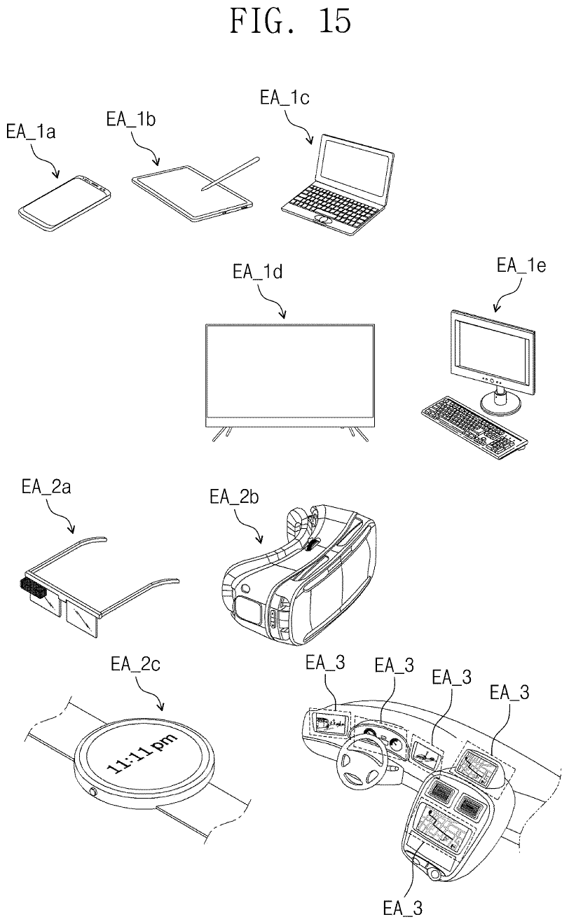

FIG. 15 shows schematic views of electronic apparatuses according to various embodiments. Referring to FIG. 15, various electronic apparatuses to which the display device according to embodiments is applied may include an electronic apparatus for displaying images, such as a smart phone EA_la, a tablet PC EA_1b, a laptop computer EA_1c, a TV EA_Id, and a desk monitor EA_le, a wearable electronic apparatus including a display module such as a smart glasses EA_2a, a head mounted display EA_2b, and a smart watch EA_2c, and a vehicle electronic apparatus EA_3 including a display module such as a center information display (CID) and a room mirror display disposed on an instrument panel, a center fascia, or a dashboard of a vehicle.

An electronic apparatus according to an embodiment may include a display device and an electronic module. The display device may include a display panel and a window disposed on the display panel. The window may be a single-layered glass substrate, include an upper surface including a convex portion and a concave portion, and have a surface roughness ranging from about 10 nm to about 1000 nm. In the window, a first concentration of silicon in a portion of the window including the upper surface may be higher than a second concentration of silicon in another portion of the window (i.e., a portion different from the portion including the upper surface). The portion of the window including the upper surface may have a thickness ranging from about 20 nm to about 200 nm. Accordingly, the window according to an embodiment may exhibit excellent durability while securing anti-glare and anti-reflection properties.

A window according to an embodiment may be formed through a window manufacturing method according to an embodiment. The window manufacturing method according to an embodiment may include steps of: providing heat; providing water; providing an etchant; and providing an acidic solution. The window having a surface roughness ranging from about 10 nm to about 1000 nm may be formed through the steps of providing heat, providing water, and providing an etchant. A window including one portion in which silicon has a relatively high concentration may be formed through the step of providing the acidic solution. Therefore, the window manufactured by the window manufacturing method according to an embodiment is a single-layered glass, and also may exhibit an excellent anti-glare property, an excellent anti-reflection property, and excellent durability.

A window manufacturing method according to an embodiment includes a step of providing heat and water on a mother glass substrate, and may thus exhibit excellent processability.

A window according to an embodiment and an electronic apparatus including the same include a single-layered glass including a portion having a high concentration of silicon, and the window may satisfy a predetermined surface roughness range, thereby exhibiting excellent durability.

Although the embodiments of the inventive concept have been described, it is understood that the inventive concept should not be limited to the example embodiments but various changes and modifications can be made by one ordinary skilled in the art within the spirit and scope of the inventive concept as hereinafter claimed.

Therefore, the technical scope of the inventive concept is not limited to the contents described in the detailed description of the specification, but should be determined by the claims.

What is claimed is:

1. A method of manufacturing a window, the method comprising:
preparing a mother glass substrate comprising silicon dioxide (SiO₂);
forming a first preliminary window by applying heat to the mother glass substrate;
forming a second preliminary window by providing water onto the first preliminary window;
forming a third preliminary window by etching the second preliminary window; and
forming a window by exposing the third preliminary window to an acidic solution.

2. The method of claim 1, wherein a temperature of the heat ranges from about 100° C. to about 200° C.

3. The method of claim 1, wherein the water is provided onto the first preliminary window through a spraying method.

4. The method of claim 1, wherein etching the second preliminary window comprises providing an etchant.

5. The method of claim 4, wherein the etchant comprises at least one of hydrogen fluoride (HF), ammonium fluoride (NH₄F), or ammonium hydrogen fluoride (NH₄HF₂).

6. The method of claim 1, wherein the acidic solution comprises at least one of hydrochloric acid (HCl), nitric acid (HNO₃), or sulfuric acid (H₂SO₄).

7. The method of claim 1, wherein a temperature of the acidic solution ranges from about 40° C. to about 80° C.

8. The method of claim 1, wherein the third preliminary window is exposed to the acidic solution for a time period ranging from about 5 minutes to about 15 minutes.

9. The method of claim 1, wherein an acidic component is contained in an amount ranging from about 20 wt % to about 80 wt % with respect to 100 wt % of a total weight of the acidic solution.

10. The method of claim 1, wherein forming the window comprises immersing the third preliminary window in the acidic solution.

11. The method of claim 1, wherein:
the window comprises an upper surface and a lower surface facing the upper surface, and
a first concentration of silicon in a portion of the window comprising the upper surface is higher than a second concentration of silicon in another portion of the window.

12. The method of claim 11, wherein the portion of the window comprising the upper surface has a thickness ranging from about 20 nm to about 200 nm.

13. The method of claim 1, wherein the window has a surface roughness ranging from about 10 nm to about 1000 nm.

14. A window which is a glass substrate comprising:
an upper surface comprising a convex portion and a concave portion;
a lower surface facing the upper surface; and
silicon dioxide,
wherein:
the upper surface has a surface roughness ranging from about 10 nm to about 1000 nm,
a first concentration of silicon in a portion of the window which is spaced apart from the lower surface and comprises the upper surface is higher than a second concentration of silicon in another portion of the window, and
the portion of the window comprising the upper surface has a thickness ranging from about 20 nm to about 200 nm.

15. The window of claim 14, wherein the window is a single layer.

16. The window of claim 14, wherein the lower surface is flat.

17. An electronic apparatus comprising:
a display device having a module region defined therein, and
an electronic module disposed to correspond to the module region,
wherein:
the display device comprises a display panel and a window disposed on the display panel,
the window which is a glass substrate comprises an upper surface comprising a convex portion and a concave portion, a lower surface facing the upper surface, and silicon dioxide,
the upper surface has a surface roughness ranging from about 10 nm to about 1000 nm,
a first concentration of silicon in a portion of the window which is spaced apart from the lower surface and comprises the upper surface is higher than a second concentration of silicon in another portion of the window, and
the portion of the window comprising the upper surface has a thickness ranging from about 20 nm to about 200 nm.

18. The electronic apparatus of claim 17, wherein the upper surface is spaced apart from the display panel, with the lower surface between the upper surface and the display panel.

19. The electronic apparatus of claim 17, wherein the window is a single layer.

20. The electronic apparatus of claim 17, wherein the lower surface of the window is flat.
